(19) United States
(12) Patent Application Publication
(10) Pub. No.: US 2022/0028710 A1
(43) Pub. Date: Jan. 27, 2022

(54) DISTRIBUTION COMPONENTS FOR SEMICONDUCTOR PROCESSING SYSTEMS

(71) Applicant: Applied Materials, Inc., Santa Clara, CA (US)

(72) Inventors: Anantha K. Subramani, San Jose, CA (US); Yang Guo, San Mateo, CA (US); Seyyed Abdolreza Fazeli, Santa Clara, CA (US); Nitin Pathak, Mumbai (IN); Badri N. Ramamurthi, Los Gatos, CA (US); Kallol Bera, Fremont, CA (US); Xiaopu Li, San Jose, CA (US); Philip A. Kraus, San Jose, CA (US); Swaminathan T. Srinivasan, Pleasanton, CA (US)

(73) Assignee: Applied Materials, Inc., Santa Clara, CA (US)

(21) Appl. No.: 16/934,227

(22) Filed: Jul. 21, 2020

(51) Int. Cl. H01L 21/67; B65G 47/90

(52) U.S. Cl. CPC H01L 21/67196; B65G 47/90; H01L 21/67167

(57) ABSTRACT

Exemplary substrate processing systems may include a chamber body defining a transfer region. The systems may include a first lid plate seated on the chamber body along a first surface of the first lid plate. The first lid plate may define a plurality of apertures through the first lid plate. The systems may include a plurality of lid stacks equal to a number of apertures of the plurality of apertures defined through the first lid plate. The systems may include a plurality of isolators. An isolator of the plurality of isolators may be positioned between each lid stack of the plurality of lid stacks and a corresponding aperture of the plurality of apertures defined through the first lid plate. The systems may include a plurality of dielectric plates. A dielectric plate of the plurality of dielectric plates may be seated on each isolator of the plurality of isolators.

### TECHNICAL FIELD

The present technology relates to semiconductor processing equipment. More specifically, the present technology relates to semiconductor chamber components to provide fluid distribution.

### BACKGROUND

Semiconductor processing systems often utilize cluster tools to integrate a number of process chambers together. This configuration may facilitate the performance of several sequential processing operations without removing the substrate from a controlled processing environment, or it may allow a similar process to be performed on multiple substrates at once in the varying chambers. These chambers may include, for example, degas chambers, pretreatment chambers, transfer chambers, chemical vapor deposition chambers, physical vapor deposition chambers, etch chambers, metrology chambers, and other chambers. The combination of chambers in a cluster tool, as well as the operating conditions and parameters under which these chambers are run, are selected to fabricate specific structures using particular process recipes and process flows.

Processing systems may use one or more components to distribute precursors or fluids into a processing region, which may improve uniformity of distribution. Some systems may provide distribution of multiple precursors or fluids for different processing operations, as well as for cleaning operations. Maintaining fluid isolation of materials while providing uniform distribution may be challenged in a number of systems, which may require incorporation of complex and expensive components.

Thus, there is a need for improved systems and components that can be used to produce high quality semiconductor devices. These and other needs are addressed by the present technology.

### SUMMARY

Exemplary substrate processing systems may include a chamber body defining a transfer region. The systems may include a first lid plate seated on the chamber body along a first surface of the first lid plate. The first lid plate may define a plurality of apertures through the first lid plate. The systems may include a plurality of lid stacks equal to a number of apertures of the plurality of apertures defined through the first lid plate. The plurality of lid stacks may at least partially define a plurality of processing regions vertically offset from the transfer region. The systems may include a plurality of isolators. An isolator of the plurality of isolators may be positioned between each lid stack of the plurality of lid stacks and a corresponding aperture of the plurality of apertures defined through the first lid plate. The systems may include a plurality of dielectric plates. A dielectric plate of the plurality of dielectric plates may be seated on each isolator of the plurality of isolators.

In some embodiments, each isolator of the plurality of isolators may define a recessed ledge on which an associated dielectric plate of the plurality of dielectric plates is seated. A gap of less than or about 5 mm may be maintained between each dielectric plate of the plurality of dielectric plates and each associated lid stack of the plurality of lid stacks. The transfer region may include a transfer apparatus rotatable about a central axis and configured to engage substrates and transfer substrates among a plurality of substrate supports within the transfer region. The systems may include a second lid plate defining a plurality of apertures through the second lid plate. The second lid plate may be seated on the plurality of lid stacks. Each aperture of the plurality of apertures through the second lid plate may access a lid stack of the plurality of lid stacks. Each lid stack of the plurality of lid stacks may include a faceplate. The second lid plate may define a first aperture accessing the faceplate of each lid stack of the plurality of lid stacks at a first position. The second lid plate may define a second aperture accessing the faceplate of each lid stack of the plurality of lid stacks at a second position.

The faceplate of each lid stack of the plurality of lid stacks may include a first plate defining a set of channels in a first surface of the first plate. The set of channels may extend from a first location proximate the first aperture through the second lid plate accessing the faceplate. The set of channels may extend to a second location at which a first aperture extends through the faceplate. The first plate may define a second aperture through the faceplate at a third location proximate the second aperture through the second lid plate accessing the faceplate. The systems may include a first manifold seated in the first aperture through the second lid plate and fluidly coupled with a first fluid source. The systems may include a second manifold seated in the second aperture through the second lid plate and fluidly coupled with a second fluid source. The second lid plate may define a third aperture accessing the faceplate of each lid stack of the plurality of lid stacks at a third position. The substrate processing system may also include a plurality of RF feedthroughs. An RF feedthrough may extend through each of the third apertures of the second lid plate and contact the faceplate of an associated lid stack. The systems may include an insulator positioned between the second lid plate and the faceplate of each lid stack of the plurality of lid stacks.

Some embodiments of the present technology may encompass substrate processing chamber faceplates. The faceplates may include a first plate defining a first set of channels in a first surface of the first plate. The first set of channels may extend from a first location to a plurality of second locations. A first aperture extending through the first plate may be defined at each second location of the plurality of second locations. The faceplates may include a second plate coupled with the first plate. The second plate may define a plurality of first apertures extending through the second plate. The second plate may define a greater number of apertures than the first plate. The faceplates may include a third plate coupled with the second plate. The third plate may include a plurality of tubular extensions extending from a first surface of the third plate towards the second plate. The third plate may include an identical number of tubular extensions as first apertures of the second plate. Each tubular extension of the third plate may be axially aligned with a corresponding first aperture through the second plate. The faceplates may include a fourth plate coupled with the third plate. The fourth plate may define a plurality of first apertures extending through the fourth plate. The fourth plate may define a greater number of apertures than the second plate.

In some embodiments, the first plate may define a second set of channels in a second surface of the first plate opposite the first surface of the first plate. Each channel of the second set of channels may extend from a first aperture through the first plate at each second location of the plurality of second locations of the first plate. Each channel of the second set of channels may extend in at least two directions along the second surface of the first plate from the first aperture through the first plate at each second location of the plurality of second locations of the first plate. A plurality of first apertures extending through the first plate may be defined at each second location of the plurality of second locations of the first plate. The first plate may define a second aperture extending through the first plate at a third location. The second plate may define a second aperture extending through the second plate. The second aperture of the second plate may be axially aligned with the second aperture of the first plate. Coupling of the second plate and the third plate may form a volume defined about the tubular extensions of the third plate. A third channel may be formed through the second aperture extending through the second plate and the second aperture extending through the first plate. The volume may be fluidly accessed through the third channel.

The third plate may define a plurality of second apertures extending through the third plate. The fourth plate may define a plurality of second apertures extending through fourth plate. A plurality of fourth channels may be formed through the plurality of second apertures extending through the third plate and the plurality of second apertures extending through the fourth plate. The volume may be fluidly accessed through the plurality of fourth channels. The first apertures of the first plate, the first apertures of the second plate, the tubular extensions of the third plate, and the first apertures of the fourth plate may form a first flow path through the substrate processing chamber faceplate that may be fluidly isolated from a second flow path through the substrate processing chamber faceplate extending through the third channel, the plurality of fourth channels, and the volume.

Some embodiments of the present technology may encompass substrate processing systems. The systems may include a processing chamber defining a processing region. The systems may include a faceplate positioned within the processing chamber. The faceplate may include a first plate defining a first set of channels in a first surface of the first plate. The first set of channels may extend from a first location to a plurality of second locations. A first aperture extending through the first plate may be defined at each second location of the plurality of second locations. The faceplate may include a second plate coupled with the first plate. The second plate may define a plurality of first apertures extending through the second plate. The second plate may define a greater number of apertures than the first plate. The faceplate may include a third plate coupled with the second plate. The third plate may include a plurality of tubular extensions extending from a first surface of the third plate towards the second plate. The third plate may include an identical number of tubular extensions as first apertures of the second plate. Each tubular extension of the third plate may be axially aligned with a corresponding first aperture through the second plate. The faceplate may include a fourth plate coupled with the third plate. The fourth plate may define a plurality of first apertures extending through the fourth plate. The fourth plate may define a greater number of apertures than the second plate.

Such technology may provide numerous benefits over conventional systems and techniques. For example, a floating dielectric plate may control ion bombardment and deposition on an overlying faceplate. Additionally, the faceplates may provide mechanisms for distributing multiple precursors uniformly into processing regions. These and other embodiments, along with many of their advantages and features, are described in more detail in conjunction with the below description and attached figures.

### BRIEF DESCRIPTION OF THE DRAWINGS

A further understanding of the nature and advantages of the disclosed technology may be realized by reference to the remaining portions of the specification and the drawings.

FIG. 1A shows a schematic top view of an exemplary processing tool according to some embodiments of the present technology.

FIG. 1B shows a schematic partial cross-sectional view of an exemplary processing system according to some embodiments of the present technology.

FIG. 2 shows a schematic isometric view of a transfer section of an exemplary substrate processing system according to some embodiments of the present technology.

FIG. 3 shows a partial schematic cross-sectional view of an exemplary system arrangement of an exemplary substrate processing system according to some embodiments of the present technology.

FIG. 4 shows a partial schematic cross-sectional view of an exemplary system arrangement of an exemplary substrate processing system according to some embodiments of the present technology.

FIG. 5 shows a schematic top view of a lid stack component of an exemplary substrate processing system according to some embodiments of the present technology.

FIG. 6A shows a schematic top view of a plate of a faceplate according to some embodiments of the present technology.

FIG. 6B shows a schematic bottom view of a plate of a faceplate according to some embodiments of the present technology.

FIG. 7A shows a schematic bottom view of a plate of a faceplate according to some embodiments of the present technology.

FIG. 7B shows a schematic bottom view of a plate of a faceplate according to some embodiments of the present technology.

FIG. 8A shows a schematic top view of a plate of a faceplate according to some embodiments of the present technology.

FIG. 8B shows a schematic cross-sectional view of a plate of a faceplate according to some embodiments of the present technology.

FIG. 9A shows a schematic top view of a plate of a faceplate according to some embodiments of the present technology.

FIG. 9B shows a schematic cross-sectional view of a plate of a faceplate according to some embodiments of the present technology.

FIG. 10 shows a schematic partial cross-sectional view of an exemplary system arrangement of an exemplary substrate processing system according to some embodiments of the present technology.

Several of the figures are included as schematics. It is to be understood that the figures are for illustrative purposes, and are not to be considered of scale or proportion unless specifically stated to be of scale or proportion. Additionally, as schematics, the figures are provided to aid comprehension and may not include all aspects or information compared to realistic representations, and may include exaggerated material for illustrative purposes.

In the appended figures, similar components and/or features may have the same reference label. Further, various components of the same type may be distinguished by following the reference label by a letter that distinguishes among the similar components. If only the first reference label is used in the specification, the description is applicable to any one of the similar components having the same first reference label irrespective of the letter.

### DETAILED DESCRIPTION

Substrate processing can include time-intensive operations for adding, removing, or otherwise modifying materials on a wafer or semiconductor substrate. Efficient movement of the substrate may reduce queue times and improve substrate throughput. To improve the number of substrates processed within a cluster tool, additional chambers may be incorporated onto the mainframe. Although transfer robots and processing chambers can be continually added by lengthening the tool, this may become space inefficient as the footprint of the cluster tool scales. Accordingly, the present technology may include cluster tools with an increased number of processing chambers within a defined footprint. To accommodate the limited footprint about transfer robots, the present technology may increase the number of processing chambers laterally outward from the robot. For example, some conventional cluster tools may include one or two processing chambers positioned about sections of a centrally located transfer robot to maximize the number of chambers radially about the robot. The present technology may expand on this concept by incorporating additional chambers laterally outward as another row or group of chambers. For example, the present technology may be applied with cluster tools including three, four, five, six, or more processing chambers accessible at each of one or more robot access positions.

As additional process locations are added, accessing these locations from a central robot may no longer be feasible without additional transfer capabilities at each location. Some conventional technologies may include wafer carriers on which the substrates remain seated during transition. However, wafer carriers may contribute to thermal non-uniformity and particle contamination on substrates. The present technology overcomes these issues by incorporating a transfer section vertically aligned with processing chamber regions and a carousel or transfer apparatus that may operate in concert with a central robot to access additional wafer positions. A substrate support may then vertically translate between the transfer region and the processing region to deliver a substrate for processing.

Each individual processing location may include a separate lid stack to provide improved and more uniform delivery of processing precursors into the separate processing regions. To improve delivery of one or more fluids or precursors through the lid stack, some embodiments of the present technology may include a multi-plate faceplate, which may provide defined flow paths to uniformly distribute precursors through the faceplate to a processing region. Because the faceplate may often be a component defining a processing region from above, the faceplate may be exposed to plasma species or deposition materials. This may increase wear and cleaning requirements for the component. In some embodiments of the present technology, an additional dielectric plate may be incorporated in the system between a substrate and the faceplate, which may provide protection of the faceplate.

Although the remaining disclosure will routinely identify specific structures, such as four-position transfer regions, for which the present structures and methods may be employed, it will be readily understood that the faceplates or components discussed may be equally employed in any number of other systems or chambers, as well as any other apparatus in which multiple components may be joined or coupled. Accordingly, the technology should not be considered to be so limited as for use with any particular chambers alone. Moreover, although an exemplary tool system will be described to provide foundation for the present technology, it is to be understood that the present technology can be incorporated with any number of semiconductor processing chambers and tools that may benefit from some or all of the operations and systems to be described.

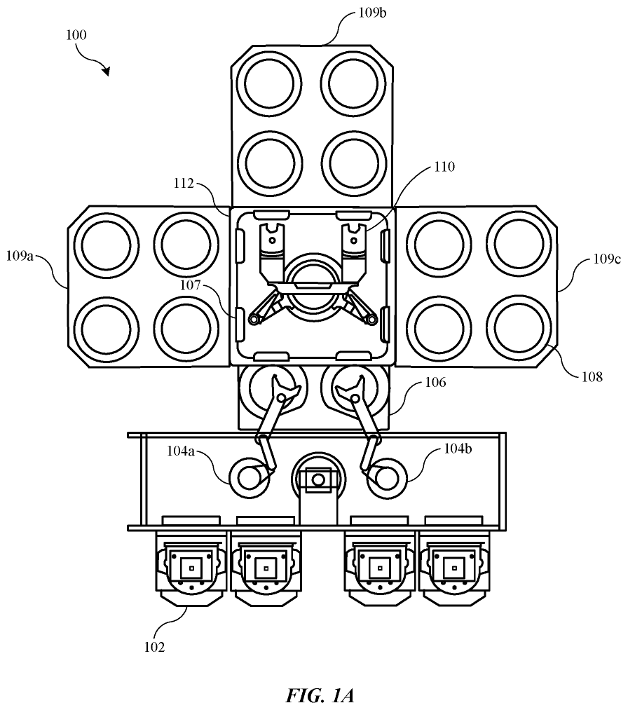

FIG. 1A shows a top plan view of one embodiment of a substrate processing tool or processing system 100 of deposition, etching, baking, and curing chambers according to some embodiments of the present technology. In the figure, a set of front-opening unified pods 102 supply substrates of a variety of sizes that are received within a factory interface 103 by robotic arms 104a and 104b and placed into a load lock or low pressure holding area 106 before being delivered to one of the substrate processing regions 108, positioned in chamber systems or quad sections 109a-c, which may each be a substrate processing system having a transfer region fluidly coupled with a plurality of processing regions 108. Although a quad system is illustrated, it is to be understood that platforms incorporating standalone chambers, twin chambers, and other multiple chamber systems are equally encompassed by the present technology. A second robotic arm 110 housed in a transfer chamber 112 may be used to transport the substrate wafers from the holding area 106 to the quad sections 109 and back, and second robotic arm 110 may be housed in a transfer chamber with which each of the quad sections or processing systems may be connected. Each substrate processing region 108 can be outfitted to perform a number of substrate processing operations including any number of deposition processes including cyclical layer deposition, atomic layer deposition, chemical vapor deposition, physical vapor deposition, as well as etch, pre-clean, anneal, plasma processing, degas, orientation, and other substrate processes.

Each quad section 109 may include a transfer region that may receive substrates from, and deliver substrates to, second robotic arm 110. The transfer region of the chamber system may be aligned with the transfer chamber having the second robotic arm 110. In some embodiments the transfer region may be laterally accessible to the robot. In subsequent operations, components of the transfer sections may vertically translate the substrates into the overlying processing regions 108. Similarly, the transfer regions may also be operable to rotate substrates between positions within each transfer region. The substrate processing regions 108 may include any number of system components for depositing, annealing, curing and/or etching a material film on the substrate or wafer. In one configuration, two sets of the processing regions, such as the processing regions in quad section 109a and 109b, may be used to deposit material on the substrate, and the third set of processing chambers, such as the processing chambers or regions in quad section 109c, may be used to cure, anneal, or treat the deposited films. In another configuration, all three sets of chambers, such as all twelve chambers illustrated, may be configured to both deposit and/or cure a film on the substrate.

As illustrated in the figure, second robotic arm 110 may include two arms for delivering and/or retrieving multiple substrates simultaneously. For example, each quad section 109 may include two accesses 107 along a surface of a housing of the transfer region, which may be laterally aligned with the second robotic arm. The accesses may be defined along a surface adjacent the transfer chamber 112. In some embodiments, such as illustrated, the first access may be aligned with a first substrate support of the plurality of substrate supports of a quad section. Additionally, the second access may be aligned with a second substrate support of the plurality of substrate supports of the quad section. The first substrate support may be adjacent to the second substrate support, and the two substrate supports may define a first row of substrate supports in some embodiments. As shown in the illustrated configuration, a second row of substrate supports may be positioned behind the first row of substrate supports laterally outward from the transfer chamber 112. The two arms of the second robotic arm 110 may be spaced to allow the two arms to simultaneously enter a quad section or chamber system to deliver or retrieve one or two substrates to substrate supports within the transfer region.

Any one or more of the transfer regions described may be incorporated with additional chambers separated from the fabrication system shown in different embodiments. It will be appreciated that additional configurations of deposition, etching, annealing, and curing chambers for material films are contemplated by processing system 100. Additionally, any number of other processing systems may be utilized with the present technology, which may incorporate transfer systems for performing any of the specific operations, such as the substrate movement. In some embodiments, processing systems that may provide access to multiple processing chamber regions while maintaining a vacuum environment in various sections, such as the noted holding and transfer areas, may allow operations to be performed in multiple chambers while maintaining a particular vacuum environment between discrete processes.

FIG. 1B shows a schematic cross-sectional elevation view of one embodiment of an exemplary processing tool, such as through a chamber system, according to some embodiments of the present technology. FIG. 1B may illustrate a cross-sectional view through any two adjacent processing regions 108 in any quad section 109. The elevation view may illustrate the configuration or fluid coupling of one or more processing regions 108 with a transfer region 120. For example, a continuous transfer region 120 may be defined by a transfer region housing 125. The housing may define an open interior volume in which a number of substrate supports 130 may be disposed. For example, as illustrated in FIG. 1A, exemplary processing systems may include four or more, including a plurality of substrate supports 130 distributed within the housing about the transfer region. The substrate supports may be pedestals as illustrated, although a number of other configurations may also be used. In some embodiments the pedestals may be vertically translatable between the transfer region 120 and the processing regions overlying the transfer region. The substrate supports may be vertically translatable along a central axis of the substrate support along a path between a first position and a second position within the chamber system. Accordingly, in some embodiments each substrate support 130 may be axially aligned with an overlying processing region 108 defined by one or more chamber components.

The open transfer region may afford the ability of a transfer apparatus 135, such as a carousel, to engage and move substrates, such as rotationally, between the various substrate supports. The transfer apparatus 135 may be rotatable about a central axis. This may allow substrates to be positioned for processing within any of the processing regions 108 within the processing system. The transfer apparatus 135 may include one or more end effectors that may engage substrates from above, below, or may engage exterior edges of the substrates for movement about the substrate supports. The transfer apparatus may receive substrates from a transfer chamber robot, such as robot 110 described previously. The transfer apparatus may then rotate substrates to alternate substrate supports to facilitate delivery of additional substrates.

Once positioned and awaiting processing, the transfer apparatus may position the end effectors or arms between substrate supports, which may allow the substrate supports to be raised past the transfer apparatus 135 and deliver the substrates into the processing regions 108, which may be vertically offset from the transfer region. For example, and as illustrated, substrate support 130a may deliver a substrate into processing region 108a, while substrate support 130b may deliver a substrate into processing region 108b. This may occur with the other two substrate supports and processing regions, as well as with additional substrate supports and processing regions in embodiments for which additional processing regions are included. In this configuration, the substrate supports may at least partially define a processing region 108 from below when operationally engaged for processing substrates, such as in the second position, and the processing regions may be axially aligned with an associated substrate support. The processing regions may be defined from above by a faceplate 140, as well as other lid stack components. In some embodiments, each processing region may have individual lid stack components, although in some embodiments components may accommodate multiple processing regions 108. Based on this configuration, in some embodiments each processing region 108 may be fluidly coupled with the transfer region, while being fluidly isolated from above from each other processing region within the chamber system or quad section.

In some embodiments the faceplate 140 may operate as an electrode of the system for producing a local plasma within the processing region 108. As illustrated, each processing region may utilize or incorporate a separate faceplate. For example, faceplate 140a may be included to define from above processing region 108a, and faceplate 140b may be included to define from above processing region 108b. In some embodiments the substrate support may operate as the companion electrode for generating a capacitively-coupled plasma between the faceplate and the substrate support. A pumping liner 145 may at least partially define the processing region 108 radially, or laterally depending on the volume geometry. Again, separate pumping liners may be utilized for each processing region. For example, pumping liner 145a may at least partially radially define processing region 108a, and pumping liner 145b may at least partially radially define processing region 108b. A blocker plate 150 may be positioned between a lid 155 and the faceplate 140 in embodiments, and again separate blocker plates may be included to facilitate fluid distribution within each processing region. For example, blocker plate 150a may be included for distribution towards processing region 108a, and blocker plate 150b may be included for distribution towards processing region 108b.

Lid 155 may be a separate component for each processing region, or may include one or more common aspects. Lid 155 may be one of two separate lid plates of the system in some embodiments. For example, a first lid plate 158 may be seated over transfer region housing 125. The transfer region housing may define an open volume, and first lid plate 158 may include a number of apertures through the lid plate separating the overlying volume into specific processing regions. In some embodiments, such as illustrated, lid 155 may be a second lid plate, and may be a single component defining multiple apertures 160 for fluid delivery to individual processing regions. For example, lid 155 may define a first aperture 160a for fluid delivery to processing region 108a, and lid 155 may define a second aperture 160b for fluid delivery to processing region 108b. Additional apertures may be defined for additional processing regions within each section when included. In some embodiments, each quad section 109—or multi-processing-region section that may accommodate more or less than four substrates, may include one or more remote plasma units 165 for delivering plasma effluents into the processing chamber. In some embodiments individual plasma units may be incorporated for each chamber processing region, although in some embodiments fewer remote plasma units may be used. For example, as illustrated a single remote plasma unit 165 may be used for multiple chambers, such as two, three, four, or more chambers up to all chambers for a particular quad section. Piping may extend from the remote plasma unit 165 to each aperture 160 for delivery of plasma effluents for processing or cleaning in embodiments of the present technology.

In some embodiments a purge channel 170 may extend through the transfer region housing proximate or near each substrate support 130. For example, a plurality of purge channels may extend through the transfer region housing to provide fluid access for a fluidly coupled purge gas to be delivered into the transfer region. The number of purge channels may be the same or different, including more or less, than the number of substrate supports within the processing system. For example, a purge channel 170 may extend through the transfer region housing beneath each substrate support. With the two substrate supports 130 illustrated, a first purge channel 170a may extend through the housing proximate substrate support 130a, and a second purge channel 170b may extend through the housing proximate substrate support 130b. It is to be understood that any additional substrate supports may similarly have a plumbed purge channel extending through the transfer region housing to provide a purge gas into the transfer region.

When purge gas is delivered through one or more of the purge channels, it may be similarly exhausted through pumping liners 145, which may provide all exhaust paths from the processing system. Consequently, in some embodiments both the processing precursors and the purge gases may be exhausted through the pumping liners. The purge gases may flow upwards to an associated pumping liner, for example purge gas flowed through purge channel 170b may be exhausted from the processing system from pumping liner 145b.

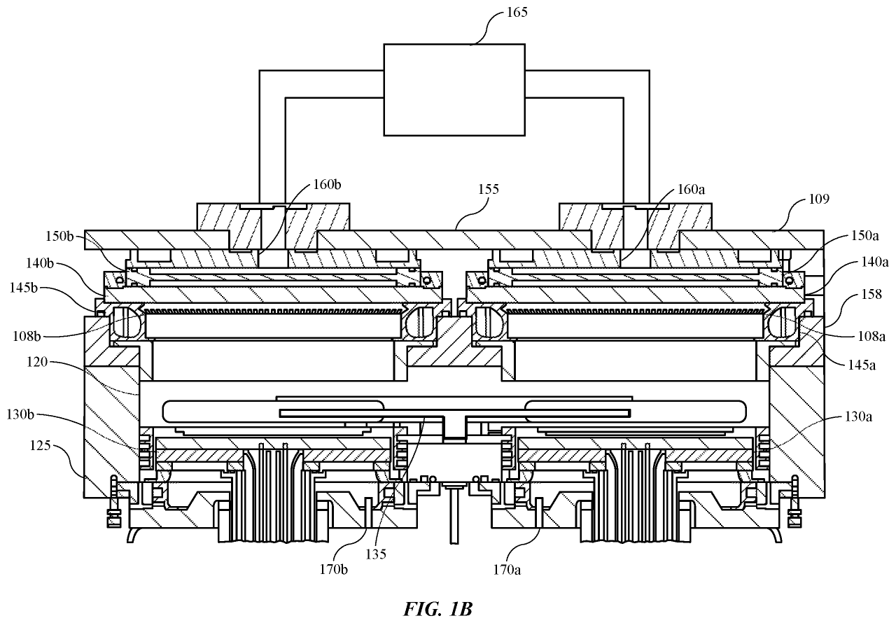

As noted, processing system 100, or more specifically quad sections or chamber systems incorporated with processing system 100 or other processing systems, may include transfer sections positioned below the processing chamber regions illustrated. FIG. 2 shows a schematic isometric view of a transfer section of an exemplary chamber system 200 according to some embodiments of the present technology. FIG. 2 may illustrate additional aspects or variations of aspects of the transfer region 120 described above, and may include any of the components or characteristics described. The system illustrated may include a transfer region housing 205 defining a transfer region in which a number of components may be included. The transfer region may additionally be at least partially defined from above by processing chambers or processing regions fluidly coupled with the transfer region, such as processing chamber regions 108 illustrated in quad sections 109 of FIG. 1A. A sidewall of the transfer region housing may define one or more access locations 207 through which substrates may be delivered and retrieved, such as by second robotic arm 110 as discussed above. Access locations 207 may be slit valves or other sealable access positions, which include doors or other sealing mechanisms to provide a hermetic environment within transfer region housing 205 in some embodiments. Although illustrated with two such access locations 207, it is to be understood that in some embodiments only a single access location 207 may be included, as well as access locations on multiple sides of the transfer region housing. It is also to be understood that the transfer section illustrated may be sized to accommodate any substrate size, including 200 mm, 300 mm, 450 mm, or larger or smaller substrates, including substrates characterized by any number of geometries or shapes.

Within transfer region housing 205 may be a plurality of substrate supports 210 positioned about the transfer region volume. Although four substrate supports are illustrated, it is to be understood that any number of substrate supports are similarly encompassed by embodiments of the present technology. For example, greater than or about three, four, five, six, eight, or more substrate supports 210 may be accommodated in transfer regions according to embodiments of the present technology. Second robotic arm 110 may deliver a substrate to either or both of substrate supports 210a or 210b through the accesses 207. Similarly, second robotic arm 110 may retrieve substrates from these locations. Lift pins 212 may protrude from the substrate supports 210, and may allow the robot to access beneath the substrates. The lift pins may be fixed on the substrate supports, or at a location where the substrate supports may recess below, or the lift pins may additionally be raised or lowered through the substrate supports in some embodiments. Substrate supports 210 may be vertically translatable, and in some embodiments may extend up to processing chamber regions of the substrate processing systems, such as processing chamber regions 108, positioned above the transfer region housing 205.

The transfer region housing 205 may provide access 215 for alignment systems, which may include an aligner that can extend through an aperture of the transfer region housing as illustrated and may operate in conjunction with a laser, camera, or other monitoring device protruding or transmitting through an adjacent aperture, and that may determine whether a substrate being translated is properly aligned. Transfer region housing 205 may also include a transfer apparatus 220 that may be operated in a number of ways to position substrates and move substrates between the various substrate supports. In one example, transfer apparatus 220 may move substrates on substrate supports 210a and 210b to substrate supports 210c and 210d, which may allow additional substrates to be delivered into the transfer chamber. Additional transfer operations may include rotating substrates between substrate supports for additional processing in overlying processing regions.

Transfer apparatus 220 may include a central hub 225 that may include one or more shafts extending into the transfer chamber. Coupled with the shaft may be an end effector 235. End effector 235 may include a plurality of arms 237 extending radially or laterally outward from the central hub. Although illustrated with a central body from which the arms extend, the end effector may additionally include separate arms that are each coupled with the shaft or central hub in various embodiments. Any number of arms may be included in embodiments of the present technology. In some embodiments a number of arms 237 may be similar or equal to the number of substrate supports 210 included in the chamber. Hence, as illustrated, for four substrate supports, transfer apparatus 220 may include four arms extending from the end effector. The arms may be characterized by any number of shapes and profiles, such as straight profiles or arcuate profiles, as well as including any number of distal profiles including hooks, rings, forks, or other designs for supporting a substrate and/or providing access to a substrate, such as for alignment or engagement.

The end effector 235, or components or portions of the end effector, may be used to contact substrates during transfer or movement. These components as well as the end effector may be made from or include a number of materials including conductive and/or insulative materials. The materials may be coated or plated in some embodiments to withstand contact with precursors or other chemicals that may pass into the transfer chamber from an overlying processing chamber.

Additionally, the materials may be provided or selected to withstand other environmental characteristics, such as temperature. In some embodiments, the substrate supports may be operable to heat a substrate disposed on the support. The substrate supports may be configured to increase a surface or substrate temperature to temperatures greater than or about 100° C., greater than or about 200° C., greater than or about 300° C., greater than or about 400° C., greater than or about 500° C., greater than or about 600° C., greater than or about 700° C., greater than or about 800° C., or higher. Any of these temperatures may be maintained during operations, and thus components of the transfer apparatus 220 may be exposed to any of these stated or encompassed temperatures. Consequently, in some embodiments any of the materials may be selected to accommodate these temperature regimes, and may include materials such as ceramics and metals that may be characterized by relatively low coefficients of thermal expansion, or other beneficial characteristics.

Component couplings may also be adapted for operation in high temperature and/or corrosive environments. For example, where end effectors and end portions are each ceramic, the coupling may include press fittings, snap fittings, or other fittings that may not include additional materials, such as bolts, which may expand and contract with temperature, and may cause cracking in the ceramics. In some embodiments the end portions may be continuous with the end effectors, and may be monolithically formed with the end effectors. Any number of other materials may be utilized that may facilitate operation or resistance during operation, and are similarly encompassed by the present technology.

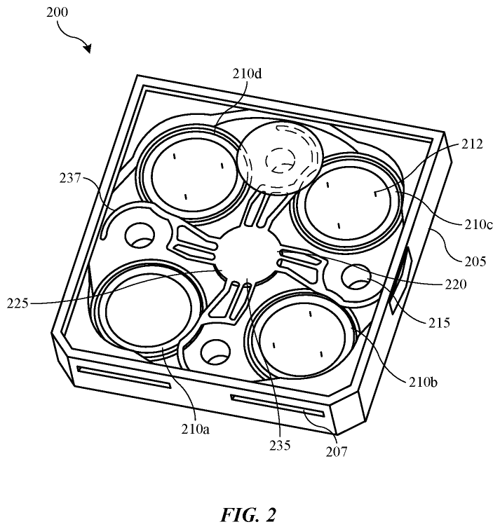

FIG. 3 shows a schematic partial cross-sectional view of an exemplary processing system 300 arrangement of an exemplary substrate processing system according to some embodiments of the present technology. The figure may illustrate aspects of the processing systems and components described above, and may illustrate additional aspects of the system. The figure may illustrate an additional version of the system with a number of components removed or modified to facilitate illustration of fluid flow through the lid stack components. It is to be understood that processing system 300 may include any aspect of any portion of the processing systems described or illustrated elsewhere, and may illustrate aspects of a lid stack incorporated with any of the systems described elsewhere. For example, processing system 300 may illustrate a portion of a system overlying the transfer region of a chamber, and may show components positioned over a chamber body defining a transfer region as previously described. It is to be understood that any previously noted components may still be incorporated, such as including a transfer region and any component described previously for a system including the components of processing system 300.

As noted previously, multi-chamber systems may include individual lid stacks for each processing region. Processing system 300 may illustrate a view of one lid stack that may be part of a multi-chamber system including two, three, four, five, six, or more processing chamber sections. It is to be understood, however, that the described lid stack components may also be incorporated in standalone chambers as well. As described above, one or more lid plates may contain the individual lid stacks for each processing region. For example, as illustrated, processing system 300 may include a first lid plate 305, which may be or include any aspect of lid plate 158 described above. For example, first lid plate 305 may be a single lid plate that may be seated on the transfer region housing, or chamber body as previously described. The first lid plate 305 may be seated on the housing along a first surface of the lid plate. Lid plate 305 may define a plurality of apertures 306 through the lid plate allowing the vertical translation of substrates into the defined processing regions as previously described.

Seated on the first lid plate 305 may be a plurality of lid stacks 310 as previously described. In some embodiments, the first lid plate 305 may define a recessed ledge as previously illustrated extending from a second surface of the first lid plate 305 opposite the first surface. The recessed ledge may extend about each aperture 306 of the plurality of apertures. Each individual lid stack 310 may be seated on a separate recessed ledge, or may be seated over non-recessed apertures as illustrated. The plurality of lid stacks 310 may include a number of lid stacks equal to a number of apertures of the plurality of apertures defined through the first lid plate. The lid stacks may at least partially define a plurality of processing regions vertically offset from the transfer region as described above. Although one aperture 306 and one lid stack 310 are illustrated and will be discussed further below, it is to be understood that the processing system 300 may include any number of lid stacks having similar or previously discussed components incorporated with the system in embodiments encompassed by the present technology. The following description may apply to any number of lid stacks or system components.

The lid stacks may include any number of components in embodiments, and may include any of the components described above. Additionally, in some embodiments of the present technology, a faceplate 315 may be incorporated that includes multiple plates, and may obviate some components of the lid stack in some embodiments. For example, a gasbox and blocker plate may be removed in some embodiments of the present technology. Faceplate 315 may be seated on an isolator 320, which may electrically insulate the faceplate from other chamber or housing components. Additionally seated on isolator 320 may be a dielectric plate 322, which may protect the faceplate, as will be described further below. An additional spacer 325 may be included, although in some embodiments a pumping liner as previously discussed may be included in this position as well. A substrate may be seated on a pedestal 330, which may at least partially define a processing region with faceplate 315.

Extending over the lid stacks 310 may be a second lid plate 335. Embodiments of the present technology may include a single second lid plate extending over all lid stacks, or may include individual second lid plates, each overlying a corresponding lid stack. Second lid plate 335 may extend fully over each lid stack of the processing system, and may provide access to the individual processing regions via a plurality of apertures defined through the second lid plate 335. Each aperture may provide fluid access to the individual lid stacks. Apertures defined through the second lid plates may include apertures providing delivery of one or more precursors, as well as apertures 337, which may provide access for an RF feedthrough 340. The RF feedthrough may facilitate operation of the faceplate 315 as a plasma-generating electrode within the system, which may allow plasma to be formed of one or more materials within the processing region. Because the faceplate may operate as a plasma-generating electrode, an insulator 345, made of any number of insulative or dielectric materials, may be positioned between the faceplate 315 and the second lid plate 335. In some embodiments a lid stack housing 350 may be included, which may operate as a heat exchanger for a fluid delivery about the lid stack, or which may otherwise extend about the lid stack.

Faceplate 315 may include a number of plates coupled together as will be described further below. The coupling may produce one or more flow paths through the faceplate. As illustrated, faceplates according to some embodiments of the present technology may define an interior volume 355, which may be formed between two or more plates. This volume may be utilized to provide an internal distribution region for one or more precursors or fluids, as will be explained in more detail below.

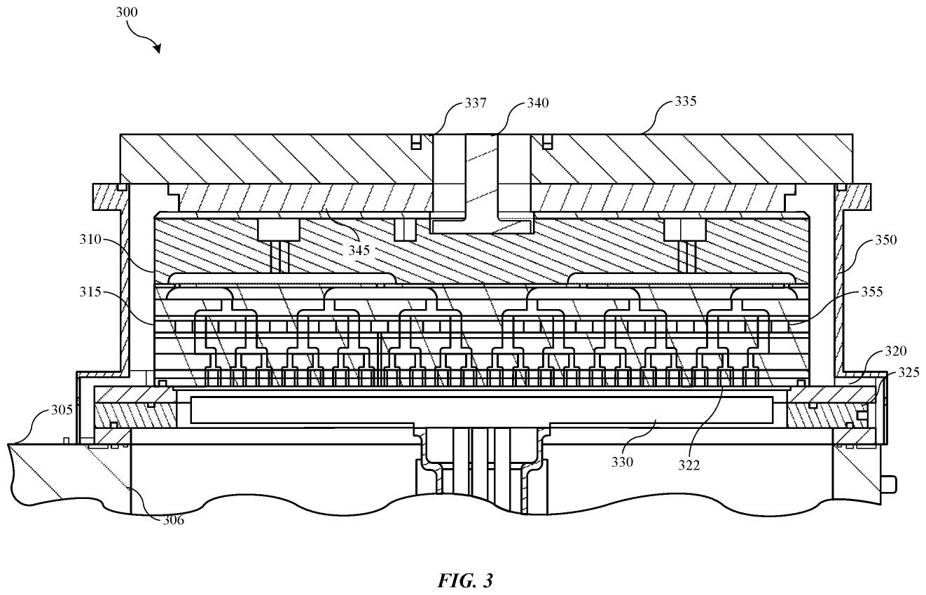

FIG. 4 shows a schematic partial cross-sectional view of exemplary processing system 400 arrangement of an exemplary substrate processing system according to some embodiments of the present technology. The figure may have the same components as FIG. 3, and may include any of the features, components, or characteristics of any component or aspect of any system described previously. Although a single processing region and lid stack components are discussed, it is to be understood that the same or previously noted components may be included with any number of processing regions as discussed above. FIG. 4 may illustrate a more detailed view of the dielectric plate 322 that may be incorporated with some embodiments of the present technology. One or more of the components previously described in any of the configurations may also be included. For example, a pedestal 330 or substrate support may at least partially define a processing region with faceplate 315, which may have any number of apertures or flow channels defined therethrough, as will be described in more detail below. Faceplate 315 may be seated on isolator 320, which may be seated on one or more other components, such as a pumping liner 405 as previously described.

Isolator 320 may define a recessed ledge 410 extending about the isolator, and on which dielectric plate 322 may be seated. Accordingly, dielectric plate 322 may be isolated from faceplate 315, and the two components may not contact one another in some embodiments of the present technology. Dielectric plate 322 may define a number of apertures 415 extending through the plate, such as greater than or about 100, greater than or about 1,000, greater than or about 5,000, greater than or about 10,000, or more. Faceplate 315 may have a number of apertures defined extending as exits from the faceplate as well, which may be the same or less than the number of apertures through the dielectric plate 322. When the number of apertures of the two components is equal, the apertures may be axially aligned between the components to limit effects on fluid flow through the dielectric plate 322, although any amount of offset may also be produced between apertures of the two components in some embodiments of the present technology.

By separating the dielectric plate from the faceplate and other components, the dielectric plate may be thermally floating, which may allow the plate to be heated by the substrate support. This may more uniformly heat the dielectric plate, which may control heat loss from the component, and any impact on precursors being delivered. Additionally, a gap 420 may be maintained between the dielectric plate 322 and the faceplate 315 in some embodiments. The gap may be maintained to prevent plasma generation between the dielectric plate and the faceplate. In some embodiments, the gap distance may be less than or about 10 mm, and may be less than or about 8 mm, less than or about 5 mm, less than or about 4 mm, less than or about 3 mm, less than or about 2 mm, or less. By incorporating a dielectric plate in the system, degradation of the faceplate may be limited or prevented in some embodiments.

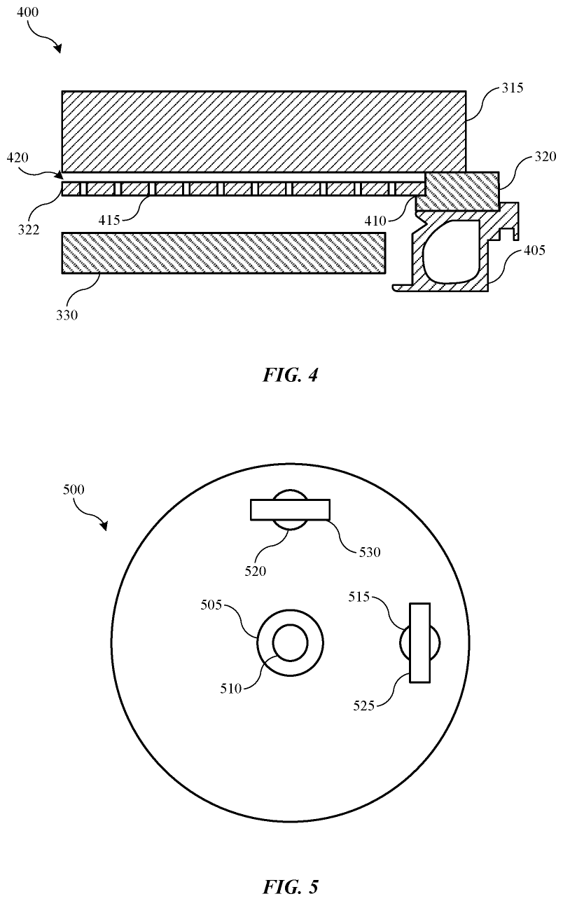

FIG. 5 shows a schematic top view of a lid stack component of an exemplary substrate processing system according to some embodiments of the present technology, and may show a second lid plate 500, or a portion of a second lid plate 500 that may be seated on one lid stack of a plurality of lid stacks. Second lid plate 500 may define one or more apertures through the plate, which may provide access for precursor delivery as well as for an RF feedthrough. For example, second lid plate 500 may define a first aperture 505, which may be centrally located, and which may allow a feedthrough 510 to be extended through the second lid plate to contact a faceplate or other lid stack components as previously described. Additional apertures may be defined to provide fluid access to the lid stack, such as to faceplates as described elsewhere. For example, a first aperture 515 may be disposed at a first location on the second lid plate, and a second aperture 520 may be disposed at a second location on the lid plate. The two apertures may provide fluid access for one or more processing gases, fluids, or precursors for semiconductor processing.

As will be described further below, in some embodiments flow paths extending from these apertures may be maintained fluidly isolated in some embodiments of the present technology. Disposed within the apertures through second lid plate 500 may be output manifolds. A first output manifold 525 may be at least partially positioned in a first aperture 515 through the second lid plate, and may at least partially seat on the second lid plate as illustrated. Additionally, a second output manifold 530 may be at least partially positioned in a second aperture 520 through the second lid plate, and may at least partially seat on the second lid plate as well. The output manifolds may be fluidly coupled with one or more precursor delivery sources, and may provide fluid access from a remote plasma source as previously described. In some embodiments the two output manifolds may be fluidly coupled with different fluid delivery sources from one another. Individual remote plasma sources may be coupled with each output manifold associated with different lid stacks as well, or one or more remote plasma sources may be coupled with multiple output manifolds as previously described.

As described previously, some embodiments of the present technology may include faceplates that may perform the function of multiple distribution components. For example, in some embodiments, faceplates according to the present technology may include a number of plates coupled with one another to define one or more flow paths through the faceplate. Faceplates according to the present technology may be incorporated with systems as previously described, and may also be included in standalone systems according to some embodiments of the present technology, in which a single processing region may be used. The faceplates may be utilized in etching, deposition, or cleaning operations, as well as any other operations in which enhanced distribution may be used as will be described below.

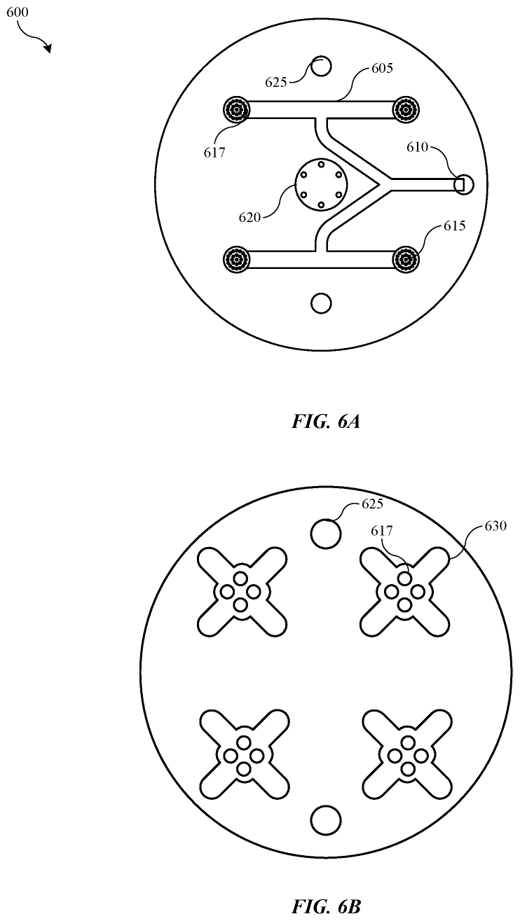

FIG. 6A shows a schematic top view of a plate 600 of a faceplate according to some embodiments of the present technology, and may illustrate a first plate of the faceplate. As illustrated, the first plate may define a number of channels 605 extending across the surface of the plate 600. As illustrated, the channels 605 may extend from a first location 610, which may correspond to, or be proximate, an aperture through a second lid plate, such as aperture 515 described above. Channels 605 may extend as illustrated from location 610 to one or more second locations 615, such as four second locations as illustrated. The channels may extend about a location 620 where an RF feedthrough may electrically couple with the plate as previously described. At each second location, an aperture, such as a first aperture 617, may be formed that extends through plate 600, which may afford access to an underlying plate, and which may further define a flow path through the faceplate.

As illustrated, in some embodiments, a plurality of apertures may be defined at each second location and extend through the plate. Plate 600 may also define a second aperture 625, which may correspond to, or be proximate, an aperture through the second lid plate, such as aperture 520 described above. As illustrated, aperture 625 may not include channels, and may extend a vertical path through the faceplate from the aperture through the second lid plate. Aperture 625 may be maintained separate from the channels formed along the surface of the plate 600, and may be isolated from the first location, the channels, and the second locations on the plate.

FIG. 6B shows a schematic bottom view of a plate of a faceplate according to some embodiments of the present technology, and may illustrate a bottom of plate 600. As illustrated, a second set of channels 630 may be defined in a bottom surface of the plate opposite the surface where first channels are formed. As illustrated, neither the first channels nor the second channels may extend through the plate, but may be recessed from the surface to provide flow paths, as may also be seen in FIG. 3 discussed previously. Second channels 630 may each extend from a first aperture 617 extending through the plate, which may allow a lateral or radial spread of a fluid being distributed. As illustrated, each second channel 630 may extend in at least two directions from the first aperture 617, where the first aperture may be centrally located between the second channels. While the illustration shows each second channel extending in four directions from the first aperture, it is to be understood that any number of channels may extend in embodiments of the present technology.

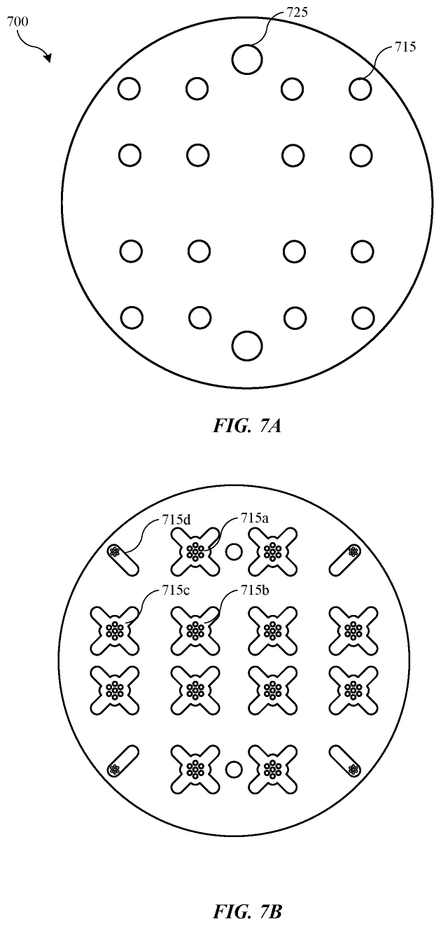

FIG. 7A shows a schematic top view of a plate 700 of a faceplate according to some embodiments of the present technology. Plate 700 may define a plurality of apertures through the plate, and may define a greater number of apertures than the first plate. As illustrated, plate 700 may define a number of first apertures 715, which may extend through the plate 700. Each first aperture 715 may be located proximate an end region of each second channel 630 formed in the bottom side of the overlying first plate. In this way, a fluid delivered through the four first apertures through the first plate, may be extended through the second channels in the first plate and then flow through eight apertures of the second plate, which may then continue the flow distribution through the faceplate. Plate 700 may also define a second aperture 725, which may be axially aligned with second aperture 625 when the plates are coupled in a faceplate, and may continue the fluid channel through the faceplate that may be fluidly isolated from the extending pattern of first apertures.

FIG. 7B shows a schematic bottom view of a plate 700 of a faceplate according to some embodiments of the present technology. Plate 700 may form recessed channels similar to first plate 600, which may extend the pattern as previously described. Plate 700 also illustrates how the pattern may be adjusted at edge regions of the faceplate. While the pattern may continue with the same number of channels extending from the first apertures through the plate, at edge regions the number of channels may be reduced by any number to accommodate the geometry of the faceplate. This may also occur to maintain second apertures isolated from the flow pattern through the first apertures. For example, as illustrated, in one set of channels extending from a single first aperture from first plate 600, to each of four first apertures 715 in the next plate, aperture 715a, aperture 715b, and aperture 715c may each continue with four channels extending from the respective aperture, which may increase the flow distribution. However, where aperture 715d may extend through the plate, maintaining the pattern may run channels past an edge of the plate. Accordingly, aperture 715d may extend to a lesser number of channels, such as the one shown, or two, or three, or any fewer channels than corresponding apertures. Additionally, in some embodiments aperture 715d may be characterized by a smaller aperture diameter or fewer apertures, or some combination, extending through the plate, which may maintain flow conductance uniformity through the plate. For any aperture from which fewer channels may extend, by reducing the aperture diameter, flow uniformity may be maintained in some embodiments.

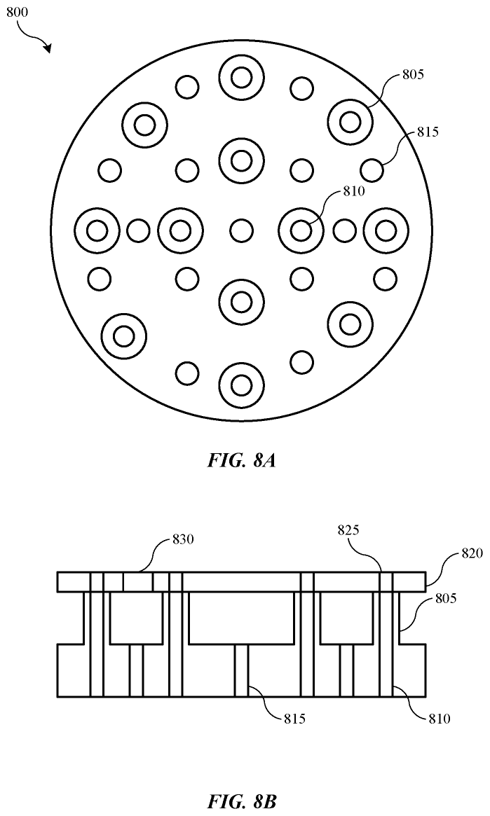

The plates may be extended for any number of plates to produce a faceplate in some embodiments of the present technology. Additionally, in some embodiments an additional flow path may be accommodated through the faceplate, such as through the second apertures through each plate. FIG. 8A shows a schematic top view of a plate 800 of a faceplate according to some embodiments of the present technology. Plate 800 may be coupled with any number of other plates to produce a faceplate according to some embodiments of the present technology. For example, plate 800 may be coupled with plate 700, or an additional plate may be included between the plates continuing the flow pattern, as illustrated in faceplate 315 above. Accordingly, plate 800 may include any number of apertures to accommodate the pattern. Any number of additional plates may be included between a second lid plate and plate 800, and each plate may include a second aperture as previously described, which may produce a vertical channel through the plates, which may be isolated from the recursive flow path through the first apertures.

Plate 800 may produce a volume between plate 800 and an overlying plate, which may allow distribution of a fluid delivered through the second apertures through the faceplate. To produce the volume while maintaining fluid isolation between the two flow paths, plate 800 may include a number of tubular extensions 805, which may extend from a surface of the plate to an overlying plate. Tubular extensions 805 may define first apertures 810 extending through the plate, which may be sized to accommodate first apertures of an overlying plate. Accordingly, when plate 800 is bonded with an overlying plate, the tubular extensions may isolate the first apertures to maintain the flow path fluidly isolated through plate 800. Accordingly, the overlying plate may not include channels on an underlying surface of the plate, but may instead simply maintain apertures from a plate overlying the plate overlying plate 800, which may then be maintained by plate 800.

For example the plate directly overlying plate 800, may have both a first surface and a second surface illustrated as plate 700 as shown in FIG. 7A, with no channels defined in either surface of the plate. Consequently, the plate may not increase the recursive pattern, but may maintain the pattern through plate 800. This may then isolate the first apertures and produce a volume about the tubular extensions of plate 800. A precursor delivered vertically through second apertures may then distribute across the faceplate within the volume defined. Plate 800 may then provide a number of second apertures 815, which may distribute the dispersed fluid through the remaining layers of the faceplate. A rim may extend about an outer edge of the plate to a height of the tubular extensions, which may maintain the volume within the faceplate in some embodiments.

FIG. 8B shows a schematic cross-sectional view of plate 800 of a faceplate according to some embodiments of the present technology, along with an overlying plate illustrating the distribution previously described. As shown, plate 800 may define a number of tubular extensions 805 extending from the surface of the plate and intersecting plate 820. Each tubular extension 805 may define an aperture 810 extending through the plate 800. Each aperture 810 may be axially aligned with a first aperture 825 through plate 820, which may maintain fluid isolation of fluids distributed through the flow path. Additionally, plate 820 may define a second aperture 830, which may continue a separate flow path extending vertically through axially aligned second apertures through each plate between the second lid plate and plate 800. A fluid distributed through a channel formed by the second apertures may then access the volume formed by plate 800, and may flow through a number of second apertures 815 into a processing region as a fully distributed material.

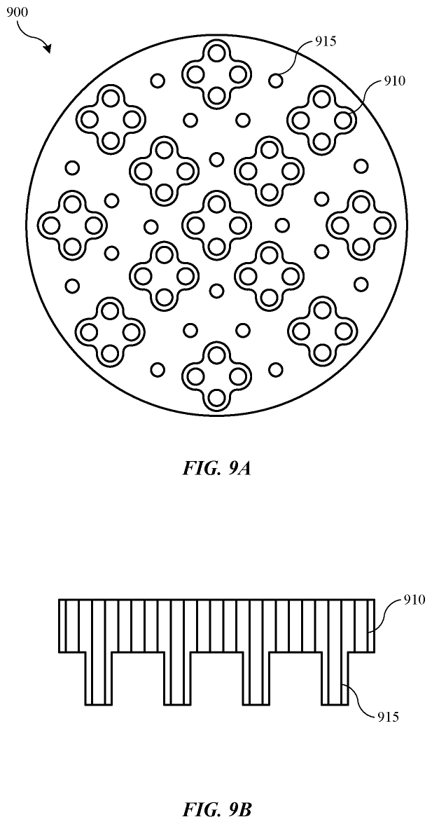

FIG. 9A shows a schematic top view of a plate 900 of a faceplate according to some embodiments of the present technology. In some embodiments, plate 900 may be a last plate in a faceplate, and may distribute one or more materials into a processing region. Plate 900 may not include channels defined in a surface of the plate, but may receive fluid distributed from overlying channels, and define apertures for an ultimate recursive increase in apertures. First apertures 910 are shown outlined in groups, where an overlying plate may be bonded, and which may provide egress from channels extending to each first aperture 910. It is to be understood that any number of apertures may be included depending on the number of channels formed in the overlying plate as previously described. Plate 900 may also define a number of second apertures 915, which may be a similar number of second apertures as each overlying plate up to plate 800, where any number of intervening plates may be included, such as illustrated for faceplate 315 described above. Accordingly, each second aperture 915 may be part of a vertical flow path extending from the internal volume formed by plate 800, and which may provide egress from the faceplate. Thus, in some embodiments the first apertures through all plates, as well as the first apertures extending through the tubular extensions of plate 800, and all second channels formed in each underlying side of each plate, may produce a first flow path through the faceplate. Additionally, the second apertures through each plate and the volume formed by plate 800 may produce a second flow path through the faceplate, which may be fluidly isolated from the first flow path when the plates of the faceplate are joined or bonded together.

FIG. 9B shows a schematic cross-sectional view of plate 900 of a faceplate according to some embodiments of the present technology, and may show an encompassed profile of the plate. For example, in some embodiments plate 900 may include a substantially planar top surface and bottom surface. Additionally, in some embodiments as illustrated, while a top surface may be substantially planar for bonding with an overlying plate, a number of recesses may be formed in a bottom surface about each first aperture 910. While apertures 915 may fully extend through the plate, a counterbore or countersunk profile may be formed about each first aperture 910, which may allow the delivered material to pool slightly, such as before passing through a dielectric plate as discussed previously, which may have a different aperture pattern. By providing the recesses, a more uniform delivery may proceed through the dielectric plate into the processing region.

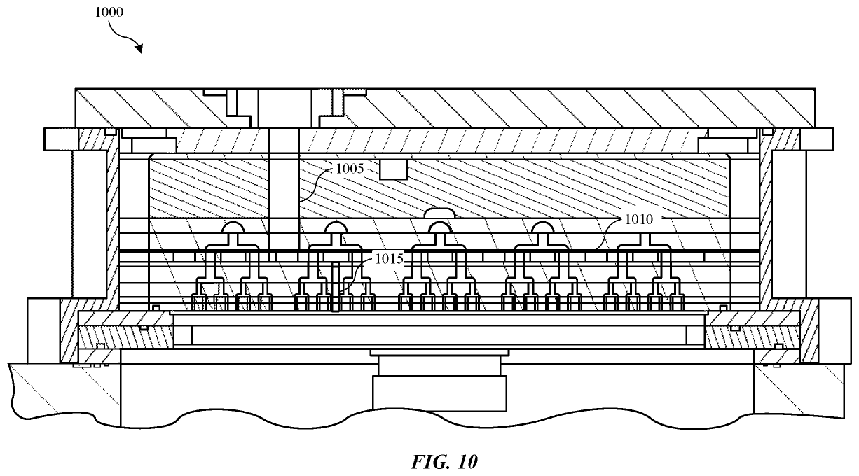

FIG. 10 shows a schematic cross-sectional view of an exemplary system 1000 arrangement of an exemplary substrate processing system according to some embodiments of the present technology. System 1000 may be similar or identical to system 300 described above, but may illustrate a sectional view for distribution of a precursor through the second apertures, instead of the recursive distribution illustrated in FIG. 3. As shown in the figure, a precursor delivered through the second lid plate may initially extend through a number of single, second apertures producing a vertical channel 1005 through the faceplate. An internal plate including tubular extensions, or any other extensions separating the plate, may form a volume 1010 at an intermediate location within the faceplate. A material delivered through vertical channel 1005, may then distribute laterally or radially within the volume 1010. A number of second apertures may be formed through the plate, which may fluidly couple with axially aligned second apertures of each subsequent plate, and which may produce a number of vertical channels 1015, providing distribution of the material from the volume to the processing region. By incorporating components according to some embodiments of the present technology, improved fluid distribution may be provided, while maintaining fluid isolation between flow paths, as well as protecting components within the lid stack.

In the preceding description, for the purposes of explanation, numerous details have been set forth in order to provide an understanding of various embodiments of the present technology. It will be apparent to one skilled in the art, however, that certain embodiments may be practiced without some of these details, or with additional details.

Having disclosed several embodiments, it will be recognized by those of skill in the art that various modifications, alternative constructions, and equivalents may be used without departing from the spirit of the embodiments. Additionally, a number of well-known processes and elements have not been described in order to avoid unnecessarily obscuring the present technology. Accordingly, the above description should not be taken as limiting the scope of the technology. Additionally, methods or processes may be described as sequential or in steps, but it is to be understood that the operations may be performed concurrently, or in different orders than listed.

Where a range of values is provided, it is understood that each intervening value, to the smallest fraction of the unit of the lower limit, unless the context clearly dictates otherwise, between the upper and lower limits of that range is also specifically disclosed. Any narrower range between any stated values or unstated intervening values in a stated range and any other stated or intervening value in that stated range is encompassed. The upper and lower limits of those smaller ranges may independently be included or excluded in the range, and each range where either, neither, or both limits are included in the smaller ranges is also encompassed within the technology, subject to any specifically excluded limit in the stated range. Where the stated range includes one or both of the limits, ranges excluding either or both of those included limits are also included.

As used herein and in the appended claims, the singular forms “a”, “an”, and “the” include plural references unless the context clearly dictates otherwise. Thus, for example, reference to “a plate” includes a plurality of such plates, and reference to “the aperture” includes reference to one or more apertures and equivalents thereof known to those skilled in the art, and so forth.

Also, the words “comprise(s)”, “comprising”, “contain(s)”, “containing”, “include(s)”, and “including”, when used in this specification and in the following claims, are intended to specify the presence of stated features, integers, components, or operations, but they do not preclude the presence or addition of one or more other features, integers, components, operations, acts, or groups.

1. A substrate processing system comprising:
a chamber body defining a transfer region;
a first lid plate seated on the chamber body along a first surface of the first lid plate, wherein the first lid plate defines a plurality of apertures through the first lid plate;
a plurality of lid stacks equal to a number of apertures of the plurality of apertures defined through the first lid plate, wherein the plurality of lid stacks at least partially define a plurality of processing regions vertically offset from the transfer region;
a plurality of isolators, wherein an isolator of the plurality of isolators is positioned between each lid stack of the plurality of lid stacks and a corresponding aperture of the plurality of apertures defined through the first lid plate; and
a plurality of dielectric plates, wherein a dielectric plate of the plurality of dielectric plates is seated on each isolator of the plurality of isolators.

2. The substrate processing system of claim 1, wherein each isolator of the plurality of isolators defines a recessed ledge on which an associated dielectric plate of the plurality of dielectric plates is seated.

3. The substrate processing system of claim 1, wherein a gap of less than or about 5 mm is maintained between each dielectric plate of the plurality of dielectric plates and each associated lid stack of the plurality of lid stacks.

4. The substrate processing system of claim 1, wherein the transfer region comprises a transfer apparatus rotatable about a central axis and configured to engage substrates and transfer substrates among a plurality of substrate supports within the transfer region.

5. The substrate processing system of claim 1, further comprising:
a second lid plate defining a plurality of apertures through the second lid plate, wherein the second lid plate is seated on the plurality of lid stacks, each aperture of the plurality of apertures through the second lid plate accessing a lid stack of the plurality of lid stacks.

6. The substrate processing system of claim 5, wherein each lid stack of the plurality of lid stacks includes a faceplate, wherein the second lid plate defines a first aperture accessing the faceplate of each lid stack of the plurality of lid stacks at a first position, and wherein the second lid plate defines a second aperture accessing the faceplate of each lid stack of the plurality of lid stacks at a second position.

7. The substrate processing system of claim 6, wherein the faceplate of each lid stack of the plurality of lid stacks comprises a first plate defining a set of channels in a first surface of the first plate, wherein the set of channels extend from a first location proximate the first aperture through the second lid plate accessing the faceplate, and wherein the set of channels extend to a second location at which a first aperture extends through the faceplate.

8. The substrate processing system of claim 7, wherein the first plate defines a second aperture through the faceplate at a third location proximate the second aperture through the second lid plate accessing the faceplate.

9. The substrate processing system of claim 8, further comprising:
a first manifold seated in the first aperture through the second lid plate and fluidly coupled with a first fluid source; and
a second manifold seated in the second aperture through the second lid plate and fluidly coupled with a second fluid source.

10. The substrate processing system of claim 8, wherein the second lid plate defines a third aperture accessing the faceplate of each lid stack of the plurality of lid stacks at a third position, the substrate processing system further comprising:
a plurality of RF feedthroughs, an RF feedthrough extending through each of the third apertures of the second lid plate and contacting the faceplate of an associated lid stack.

11. The substrate processing system of claim 10, further comprising:
an insulator positioned between the second lid plate and the faceplate of each lid stack of the plurality of lid stacks.

12. A substrate processing chamber faceplate comprising:
a first plate defining a first set of channels in a first surface of the first plate, wherein the first set of channels extend from a first location to a plurality of second locations, and wherein a first aperture extending through the first plate is defined at each second location of the plurality of second locations;
a second plate coupled with the first plate, wherein the second plate defines a plurality of first apertures extending through the second plate, and wherein the second plate defines a greater number of apertures than the first plate;
a third plate coupled with the second plate, wherein the third plate comprises a plurality of tubular extensions extending from a first surface of the third plate towards the second plate, wherein the third plate includes an identical number of tubular extensions as first apertures of the second plate, and wherein each tubular extension of the third plate is axially aligned with a corresponding first aperture through the second plate; and
a fourth plate coupled with the third plate, wherein the fourth plate defines a plurality of first apertures extending through the fourth plate, and wherein the fourth plate defines a greater number of apertures than the second plate.

13. The substrate processing chamber faceplate of claim 12, wherein the first plate defines a second set of channels in a second surface of the first plate opposite the first surface of the first plate, and wherein each channel of the second set of channels extends from a first aperture through the first plate at each second location of the plurality of second locations of the first plate.

14. The substrate processing chamber faceplate of claim 13, wherein each channel of the second set of channels extends in at least two directions along the second surface of the first plate from the first aperture through the first plate at each second location of the plurality of second locations of the first plate.

15. The substrate processing chamber faceplate of claim 12, wherein a plurality of first apertures extending through the first plate is defined at each second location of the plurality of second locations of the first plate.

16. The substrate processing chamber faceplate of claim 12, wherein the first plate defines a second aperture extending through the first plate at a third location, wherein the second plate defines a second aperture extending through the second plate, and wherein the second aperture of the second plate is axially aligned with the second aperture of the first plate.

17. The substrate processing chamber faceplate of claim 16, wherein coupling of the second plate and the third plate forms a volume defined about the tubular extensions of the third plate, wherein a third channel is formed through the second aperture extending through the second plate and the second aperture extending through the first plate, and wherein the volume is fluidly accessed through the third channel.

18. The substrate processing chamber faceplate of claim 17, wherein the third plate defines a plurality of second apertures extending through the third plate, wherein the fourth plate defines a plurality of second apertures extending through fourth plate, wherein a plurality of fourth channels is formed through the plurality of second apertures extending through the third plate and the plurality of second apertures extending through the fourth plate, and wherein the volume is fluidly accessed through the plurality of fourth channels.

19. The substrate processing chamber faceplate of claim 18, wherein the first apertures of the first plate, the first apertures of the second plate, the tubular extensions of the third plate, and the first apertures of the fourth plate form a first flow path through the substrate processing chamber faceplate that is fluidly isolated from a second flow path through the substrate processing chamber faceplate extending through the third channel, the plurality of fourth channels, and the volume.

20. A substrate processing system comprising:
a processing chamber defining a processing region; and
a faceplate positioned within the processing chamber, wherein the faceplate comprises:
a first plate defining a first set of channels in a first surface of the first plate, wherein the first set of channels extend from a first location to a plurality of second locations, and wherein a first aperture extending through the first plate is defined at each second location of the plurality of second locations,
a second plate coupled with the first plate, wherein the second plate defines a plurality of first apertures extending through the second plate, and wherein the second plate defines a greater number of apertures than the first plate,
a third plate coupled with the second plate, wherein the third plate comprises a plurality of tubular extensions extending from a first surface of the third plate towards the second plate, wherein the third plate includes an identical number of tubular extensions as first apertures of the second plate, and wherein each tubular extension of the third plate is axially aligned with a corresponding first aperture through the second plate, and
a fourth plate coupled with the third plate, wherein the fourth plate defines a plurality of first apertures extending through the fourth plate, and wherein the fourth plate defines a greater number of apertures than the second plate.
